(19) United States
(12) Patent Application Publication
(10) Pub. No.: US 2024/0006152 A1
(43) Pub. Date: Jan. 4, 2024

(54) ETCHING METHOD AND ETCHING APPARATUS

(71) Applicant: Tokyo Electron Limited, Tokyo (JP)

(72) Inventors: Maju TOMURA, Miyagi (JP); Nobuyuki FUKUI, Miyagi (JP); Yoshihide KIHARA, Miyagi (JP)

(73) Assignee: Tokyo Electron Limited, Tokyo (JP)

(21) Appl. No.: 18/368,110

(22) Filed: Sep. 14, 2023

Related U.S. Application Data
(63) Continuation of application No. PCT/JP2022/012748, filed on Mar. 18, 2022.

(30) Foreign Application Priority Data
Mar. 30, 2021 (JP) 2021-057609

(51) Int. Cl. H01J 37/32; H01L 21/311; H01L 21/033

(52) U.S. Cl. CPC H01J 37/32174; H01J 37/32155; H01L 21/31144; H01L 21/0332; H01J 2237/3341; H01J 37/32027

(57) ABSTRACT

A method for etching a substrate includes: (a) providing a substrate processing apparatus including a processing chamber that forms a processing space, a substrate support provided inside the processing chamber to hold a substrate, and a power supply that supplies a bias power to at least the substrate support; (b) providing the substrate on the substrate support, the substrate including an underlying layer and an organic material layer on the underlying layer; (c) generating plasma in the processing chamber; and (d) repeating a predetermined cycle including an ON time during which the bias power is supplied to the substrate support and an OFF time during which the bias power is not supplied to the substrate support. The OFF time is 10 msec or longer.

### CROSS-REFERENCE TO RELATED APPLICATIONS

This application is a continuation application of International Patent Application No. PCT/JP2022/012748, filed on Mar. 18, 2022, which claims priority from Japanese patent application No. 2021-057609, filed on Mar. 30, 2021, all of which are incorporated herein in their entireties by reference.

### TECHNICAL FIELD

The present disclosure relates to an etching method and an etching apparatus.

### BACKGROUND

Japanese Patent Laid-Open Publication No. 2010-109373 discloses a method for controlling a critical dimension (CD) of an etching feature of an etching layer in a stack of layers including a patterned photoresist mask, an intermediate mask layer disposed below the photoresist mask, a functional organic mask layer disposed below the intermediate mask layer, and the etching layer disposed below the functional organic mask layer.

### SUMMARY

According to an aspect of the present disclosure, a method for etching a substrate includes: (a) providing a substrate processing apparatus including a processing chamber that forms a processing space, a substrate support provided inside the processing chamber to hold the substrate, and a power supply that supplies a bias power to at least the substrate support; (b) providing the substrate on the substrate support, the substrate including an underlying layer and an organic material layer on the underlying layer; (c) generating plasma in the processing chamber; and (d) repeating a predetermined cycle including an ON time during which the bias power is supplied to the substrate support and an OFF time during which the bias power is not supplied to the substrate support. The OFF time is 10 msec or longer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view schematically illustrating an example of a configuration of a plasma processing system.

FIGS. 2A to 2C are views illustrating an etching target layer and an organic material layer before and after an etching process.

FIG. 3 is a view illustrating the deterioration of roundness and the occurrence of bowing in the organic material layer.

FIG. 4 is a graph illustrating an example of supply of a radio-frequency power to a substrate support body.

FIG. 5 is a view illustrating an example of a result of an etching process according to an embodiment.

FIG. 6 is a view illustrating an example of a result of an etching process according to an embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In a semiconductor device manufacturing process, an etching process is performed on an etching target layer (e.g., a silicon-containing film) stacked on the surface of a semiconductor substrate (hereinafter, simply referred to as a “substrate”) using a patterned mask layer (e.g., an amorphous carbon layer (ACL)) as a mask. The pattern on the mask layer is generally formed by a plasma processing apparatus.

Japanese Patent Laid-Open Publication No. 2010-109373 above discloses a method of etching a mask layer (the intermediate mask layer and the functional organic layer) in a plasma processing apparatus (etching chamber). Specifically, the substrate with the patterned mask layer is carried into the etching chamber, and an etching gas is introduced into the etching chamber. Then, a radio frequency (RF) is supplied from a radio-frequency source to an electrode to form plasma inside the chamber, so that the intermediate mask layer and the functional organic layer are sequentially and selectively etched.

When forming a pattern on the mask layer, it is crucial to transfer the hole shape at the top of a hole directly to the hole shape at the bottom of the hole. However, with the recent tendency where a pattern formed on the substrate surface becomes finer, it is demanded to form a hole (mask pattern) having a high aspect ratio in the mask layer, which may cause the deterioration of roundness at the bottom of the hole.

In a conventional method of improving the roundness, a bias radio-frequency power with several hundreds of Hz or more has been supplied in an ON/OFF manner. However, since the improvement of roundness at the bottom of the hole and the occurrence of bowing at the side wall of the hole stand in the trade-off relationship, the method has a difficulty in controlling the cross-sectional shape of the hole to be uniform.

The present disclosure has been made in consideration of the circumstances above, and has an object to appropriately form a hole with a high aspect ratio in an organic material layer that serves as a mask used for forming a pattern on an etching target layer. Hereinafter, a plasma processing system according to an embodiment of the present disclosure and a plasma processing method including an etching method according to an embodiment of the present disclosure will be described with reference to the drawings. In the description herein and the drawings, components having substantially the same function or configuration will be denoted by the same reference numerals, and overlapping descriptions thereof will be omitted.

In the description herein below, the “duty ratio” refers to the ratio of ON time (time during which an RF power is supplied) (ON duty) per cycle (ON time+OFF time) of an RF power supplied in a pulse form.

Further, in the descriptions herein below, the “roundness” refers to the ratio of the smallest diameter to the largest diameter (min diameter/max diameter) in the cross-sectional shape of a hole formed in an organic material layer.

<Plasma Processing System>

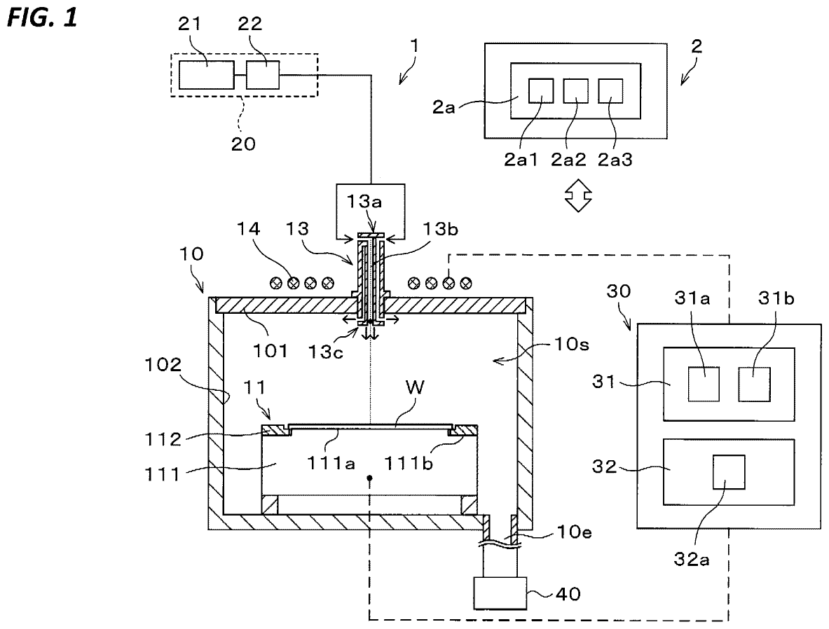

First, a plasma processing system according to an embodiment will be described. FIG. 1 is a vertical cross-sectional view schematically illustrating a configuration of a plasma processing system.

The plasma processing system includes an inductively coupled plasma (ICP) processing apparatus 1 and a control unit 2. The plasma processing apparatus 1 includes a plasma processing chamber 10, a gas supply unit 20, a power supply 30, and an exhaust system 40. The plasma processing chamber 10 includes a dielectric window 101. Further, the plasma processing apparatus 1 includes a substrate support body 11, a gas introduction unit, and an antenna 14. The substrate support body 11 is disposed inside the plasma processing chamber 10. The antenna 14 is disposed on or above the plasma processing chamber 10 (i.e., on or above the dielectric window 101). The plasma processing chamber 10 has a plasma processing space 10s defined by the dielectric window 101, the side wall 102 of the plasma processing chamber 10, and the substrate support body 11. The plasma processing chamber 10 includes at least one gas supply port for supplying at least one processing gas into the plasma processing space 10s, and at least one gas discharge port for discharging a gas from the plasma processing space 10s.

The substrate support body 11 includes a main body 111 and a ring assembly 112. The main body 111 includes a central region 111a for supporting a substrate (wafer) W (substrate support surface), and an annular region 111b for supporting the ring assembly 112 (ring support surface). The annular region 111b of the main body 111 surrounds the central region 111a of the main body 111 in plan view. The substrate W is disposed on the central region 111a, and the ring assembly 112 is disposed on the annular region 111b to surround the substrate W disposed on the central region 111a.

In an embodiment, the main body 111 includes a base (not illustrated) and an electrostatic chuck (not illustrated). The base includes a conductive member. The conductive member of the base functions as a lower electrode. The electrostatic chuck is disposed on the base. The upper surface of the electrostatic chuck has the central region 111a and the annular region 111b described above. The ring assembly 112 includes one or more annular members, and at least one of the one or more annular members is an edge ring.

Although not illustrated, the substrate support body 11 may include a temperature adjustment module configured to adjust at least one of the electrostatic chuck, the ring assembly 112, and the substrate W to a target temperature. The temperature adjustment module may include a heater, a heat transfer medium, a flow path, or a combination thereof. A heat transfer fluid such as brine or a gas flows through the flow path. Further, the substrate support body 11 may include a heat transfer gas supply unit configured to supply a heat transfer gas to the space between the rear surface of the substrate W and the substrate support surface.

The gas introduction unit is configured to introduce at least one processing gas from the gas supply unit 20 into the plasma processing space 10s. In an embodiment, the gas introduction unit includes a center gas injector (CGI) 13. The center gas injector 13 is disposed above the substrate support body 11, and attached to a central opening formed in the dielectric window 101. The center gas injector 13 has at least one gas supply port 13a, at least one gas flow path 13b, and at least one gas introduction port 13c. A processing gas supplied to the gas supply port 13a passes through the gas flow path 13b and is introduced into the plasma processing space 10s from the gas introduction port 13c. In addition to or instead of the center gas injector 13, the gas introduction unit may include one or more side gas injectors (SGI) attached to one or more openings formed in the side wall 102.

The gas supply unit 20 may include at least one gas source 21 and at least one flow rate controller 22. In an embodiment, the gas supply unit 20 is configured to supply at least one processing gas from the corresponding gas source 21 to the center gas injector 13 via the corresponding flow rate controller 22. Each flow rate controller 22 may include, for example, a mass flow controller or a pressure-controlled flow rate controller. Further, the gas supply unit 20 may include one or more flow rate modulation devices that modulate or pulse the flow rate of at least one processing gas.

The power supply 30 includes an RF power supply 31 coupled to the plasma processing chamber 10 via at least one impedance matching circuit. The RF power supply 31 is configured to supply at least one RF signal (RF power), such as a source RF signal or a bias RF signal, to the conductive member (lower electrode) of the substrate support body 11 and the antenna 14. Thus, plasma is formed from at least one processing gas supplied into the plasma processing space 10s. Accordingly, the RF power supply 31 may function as at least a portion of a plasma generation unit configured to generate plasma from one or more processing gases in the plasma processing chamber 10. By supplying the bias RF signal to the lower electrode, a bias potential is generated on the substrate W, so that ions in the formed plasma may be attracted into the substrate W.

In an embodiment, the RF power supply 31 includes a first RF generation unit 31a and a second RF generation unit 31b. The first RF generation unit 31a is coupled to the antenna 14, and configured to generate a source RF signal for plasma generation (source RF power; hereinafter, may be referred to as an “RF power HF”) via at least one impedance matching circuit. In an embodiment, the source RF signal has a frequency in the range of 13 MHz to 150 MHz. In an embodiment, the first RF generation unit 31a may be configured to generate a plurality of source RF signals having different frequencies. One or a plurality of generated source RF signals are supplied to the antenna 14.

The second RF generation unit 31b is coupled to the lower electrode via at least one impedance matching circuit, and configured to generate a bias RF signal (bias RF power; hereinafter, may be referred to as an “RF power LF”) as a bias power. In an embodiment, the bias RF signal has a lower frequency than that of the source RF signal. In an embodiment, the bias RF signal has a frequency in the range of 400 kHz to 13.56 MHz. In an embodiment, the second RF generation unit 31b may be configured to generate a plurality of bias RF signals having different frequencies. The generated one or plurality of bias RF signals are supplied to the lower electrode. In various embodiments, at least one of the source RF signal and the bias RF signal may be pulsed.

In an embodiment, the power supply 30 may further include a DC power supply 32 coupled to the plasma processing chamber 10. The DC power supply 32 includes a bias DC generation unit 32a. In an embodiment, the bias DC generation unit 32a is connected to the lower electrode, and configured to generate a bias DC signal. The generated bias DC signal is supplied to the lower electrode. In an embodiment, the bias DC signal may be supplied to another electrode such as an electrode inside the electrostatic chuck. In various embodiments, the bias DC signal may be pulsed. The bias DC generation unit 32a may be provided in addition to the RF power supply 31, and may be provided in place of the second RF generation unit 31b.

The antenna 14 includes one or a plurality of coils. In an embodiment, the antenna 14 may include an outer coil and an inner coil that are arranged coaxially. In this case, the RF generation unit 31 may be connected to both or either one of the outer coil and the inner coil. In the former case, the same RF generation unit may be connected to both the outer coil and the inner coil, or separate RF generation units may be connected to the outer coil and the inner coil, respectively.

The exhaust system 40 may be connected to a gas discharge port 10e formed at, for example, the bottom of the plasma processing chamber 10. The exhaust system 40 may include a pressure regulation valve and a vacuum pump. The pressure in the plasma processing space 10s is regulated by the pressure regulation valve. The vacuum pump may include a turbo molecular pump, a dry pump, or a combination thereof.

The control unit 2 processes computer-executable commands to cause the plasma processing apparatus 1 to perform various processes described herein. The control unit 2 may be configured to control each component of the plasma processing apparatus 1 to perform the various processes described herein. In an embodiment, a portion of the control unit 2 or the entire control unit 2 may be included in the plasma processing apparatus 1. The control unit 2 may include, for example, a computer 2a. The computer 2a may include, for example, a processing unit (CPU) 2a1, a storage unit 2a2, and a communication interface 2a3. The processing unit 2a1 may be configured to perform various control operations based on programs stored in the storage unit 2a2. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

While various embodiments have been described, various additions, omissions, substitutions, and changes may be made without being limited to the embodiments described above. Further, elements of different embodiments may be combined with each other, so as to form another embodiment.

For example, in the present embodiment, the plasma processing system includes the inductively coupled plasma (ICP) processing apparatus 1. However, the configuration of the plasma processing system is not limited thereto. The plasma processing system may include a processing apparatus provided with, for example, a capacitively coupled plasma (CCP) generator, an electron-cyclotron-resonance (ECR) plasma generator, a helicon wave excitation plasma (HWP) generator, or a surface wave plasma (SWP) generator. Further, the plasma processing system may use processing apparatuses provided with various types of plasma generators such as an alternating current (AC) plasma generator and a direct current (DC) plasma generator.

<Plasma Processing Method>

Next, descriptions will be made on an etching process performed on the organic material layer using the plasma processing apparatus 1 configured as described above.

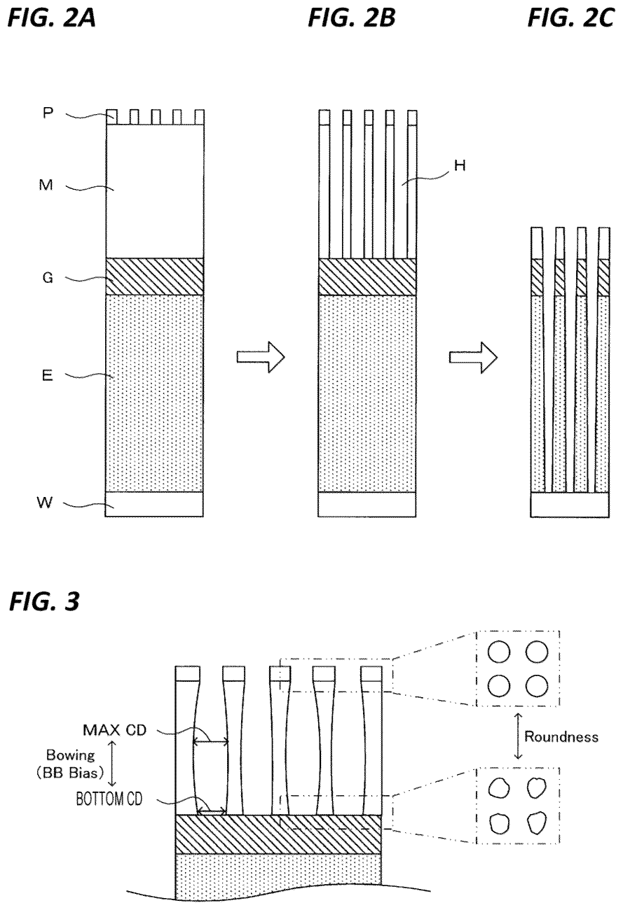

In the present embodiment, as illustrated in FIG. 2A, an etching target layer E (e.g., SiOx film), an underlying layer G (e.g., SiN film), an organic material layer M, and a mask pattern P are formed on the substrate W in this order from bottom. The organic material layer M includes, for example, an amorphous carbon layer (ACL). Then, in the plasma processing apparatus 1, patterns are formed in the organic material layer M by the etching method of the present embodiment as illustrated in FIG. 2B. Alternatively, patterns may be formed in the etching target layer E by performing the etching process on the etching target layer E while using the organic material layer M as a mask.

First, the substrate W is carried into the plasma processing chamber 10 and disposed on the substrate support body 11. Then, the DC voltage is supplied to the electrode inside the electrostatic chuck, so that the substrate W is electrostatically adsorbed to the electrostatic chuck by the Coulomb force. After the carry-in of the substrate W, the inside of the plasma processing chamber 10 may be decompressed to a desired degree of vacuum by the exhaust system 40.

Next, a processing gas including an etching gas for the organic material layer M is supplied from the gas supply unit 20 into the plasma processing space 10s through the center gas injector 13. The etching gas for the organic material layer M may be, for example, at least one oxygen-containing gas selected from the group consisting of CO gas, CO₂ gas, O₂ gas, O₃ gas), COS gas, and H₂O gas. The processing gas may include a dilution gas such as Ar gas. Further, the first RF generation unit 31a supplies the RF power HF for plasma generation to the antenna 14 to excite the processing gas thereby generating plasma. Further, the second RF generation unit 31b supplies the RF power LF for bias to the lower electrode to draw ions into the substrate W thereby etching the organic material layer M. As illustrated in FIG. 2B, the organic material layer M is etched, and holes H are formed as mask patterns in the organic material layer M. Each hole H formed in the organic material layer M may be referred to as a “recess” in the descriptions herein below.

Here, when the hole H is formed having a high aspect ratio to cater to the recent demand for a finer mask pattern, the amount of ions arriving at the bottom of the hole H decreases as the depth of the hole H increases. As a result, the roundness at the bottom of the hole H may deteriorate as described above.

As a method for improving the roundness at the bottom of the hole H, conventionally, the bias RF power LF with the frequency of several hundreds of Hz or more has been turned ON/OFF, that is, the supply and the cut-off of the RF power LF have repeated in a predetermined cycle. In this case, however, a so-called bowing (uneven CD value of the hole H) may occur, in which the side wall of the hole H is bowed (see, e.g., FIG. 3).

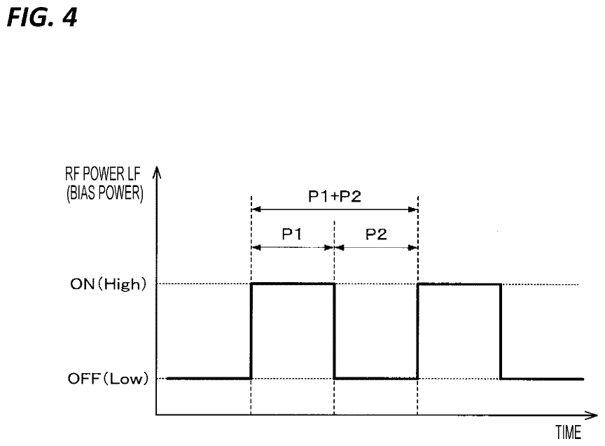

Accordingly, in the present embodiment, in order to suppress the occurrence of bowing in the hole H and the deterioration of roundness at the bottom of the hole H, the RF power LF as a bias power is supplied to the substrate support body during the etching in a pulse form where ON/OFF repeat in a predetermined cycle. In an embodiment, as illustrated in FIG. 4, the RF power LF having a frequency of 100 Hz or less and a duty ratio of 20% or more and 60% or less is supplied to the substrate support body (lower electrode). Here, the frequency defines a cycle for repeating a first period P1 during which the RF power LF is supplied (turned ON) to the substrate support body, and a second period P2 during which the supply of the RF power LF is stopped (turned OFF) (hereinafter, also referred to as a “pulse frequency”). The duty ratio indicates the ratio of time of the first period P1 to the total time of the first period P1 and the second period P2 (P1/(P1+P2)). Alternatively, as illustrated in FIG. 4, the RF power LF may be supplied to the substrate support body (lower electrode) by a High/Low control, instead of the pulse where ON/OFF repeat.

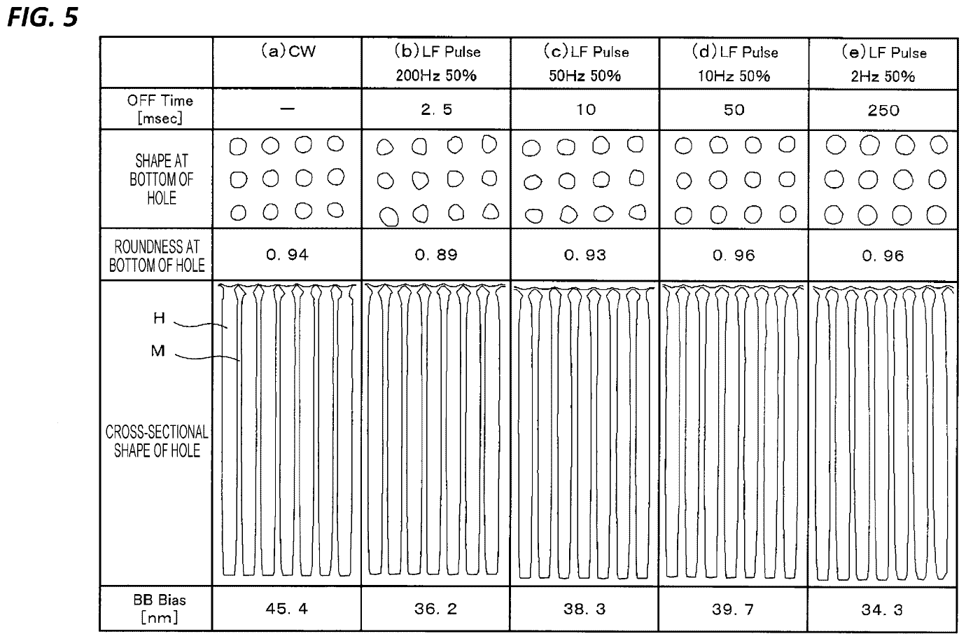

FIG. 5 is a view schematically illustrating an example of the result of the etching process according to an embodiment, and represents “roundness” and “bowing CD value (BB Bias: a difference between a Max CD value and a bottom CD value of the hole H)” in each case of Comparative Example (a) where the RF power LF is supplied in a continuous wave (CW) form, and Examples (b) to (e) where the RF power LF is supplied in a pulse form with the pulse frequency of 2 Hz to 200 Hz and the duty ratio of 50%.

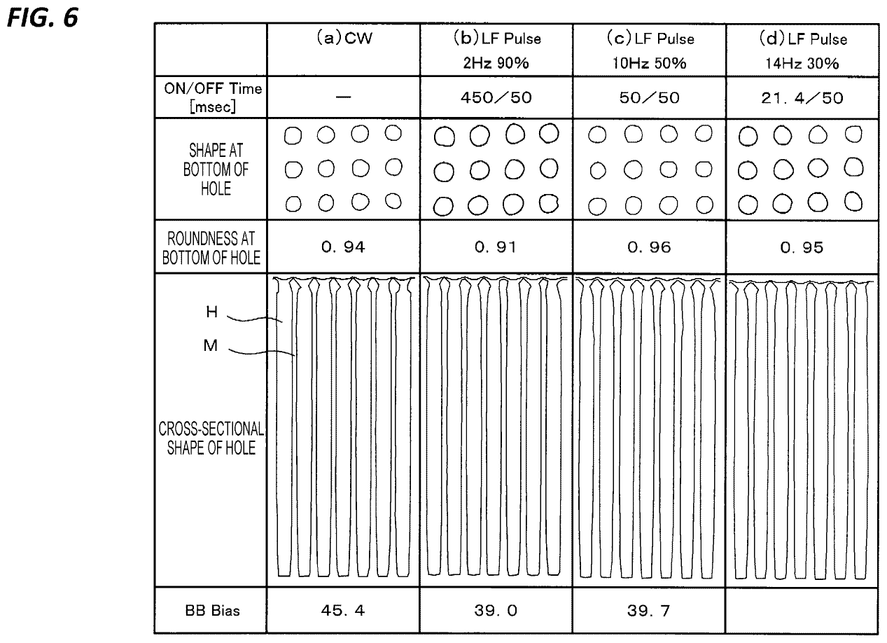

FIG. 6 is a view schematically illustrating an example of the result of the etching process according to an embodiment, and represents “roundness” and “bowing CD value” in each case of Comparative Example (a) where the RF power LF is supplied in a continuous wave form, and Examples (b) to (d) where the RF power LF is supplied in a pulse form with the duty ratio of 30% to 90% and the OFF time of 50 msec (time of the pulse wave during which the RF power LF is not supplied). Comparative Example (a) of FIG. 6 is the same as Comparative Example (a) of FIG. 5.

As illustrated in (a) of FIG. 5 and (a) of FIG. 6, when the RF power LF is supplied to the lower electrode in the continuous wave form during the etching process, it is observed that the roundness at the bottom of the hole H improves to some extent, but the bowing occurs at the side wall of the hole H. Specifically, it is observed that the bottom of the hole H (hole bottom shape) is roughly circular, but a difference occurs between the Max CD value and the bottom CD value in the cross-sectional shape of the hole H so that the hole H has the bowed shape.

Meanwhile, as illustrated in (b) to (e) of FIG. 5, it is observed that the roundness at the bottom of the hole H improves as the cycle of ON/OFF of the RF power LF supplied to the lower electrode during the etching process lengthens. Specifically, in (c) where the pulse frequency is 50 Hz, the roundness becomes nearly the same as that in Comparative Example (a), and in (d) where the pulse frequency is 10 Hz or less, the roundness comes close to “1,” that is, the difference between the maximum diameter and the minimum diameter of the hole H decreases, improving the roundness.

Further, as illustrated in (b) to (d) of FIG. 6, it is observed that the bowing of the hole H is suppressed regardless of the duty ratio of the RF power LF supplied to the lower electrode. Further, from a comparison between (e) of FIG. 5 and (b) of FIG. 6, when the duty ratio is changed under the same pulse frequency condition, it is observed that the bowing improves as the duty ratio is small. In other words, it is predicted that the bowing of the hole H tends to improve as the duty ratio of the RF power LF decreases.

Meanwhile, as illustrated in (b) to (d) of FIG. 6, when the duty ratio of the RF power LF is increased while fixing the OFF time (50 msec in the example in FIG. 6), it may be seen that the roundness tends to improve since the pulse frequency, which is the cycle of ON/OFF of the RF power LF, decreases.

In this way, by supplying the RF power LF to the lower electrode in the low-frequency pulse form, the roundness at the bottom of the hole H may be improved, and the occurrence of bowing in the hole H may be suppressed.

That is, when the bias RF power LF is supplied in the pulse form, ions are actively attracted into the hole H to proceed with the etching during the ON time of the RF power LF, and during the OFF time, ions attracted to the bottom of the hole H decrease thereby increasing the action to uniformly and firmly generate a polymer (reaction product resulting from the etching gas) as a protective film on the side wall of the hole H. In other words, the polymer formed during the OFF time may protect the side wall of the hole H from the etching during the ON time, and as a result, the occurrence of bowing is suppressed.

Further, when the low frequency is used for the RF power LF, ions arriving at the bottom of the hole H with the high aspect ratio may be increased, and as a result, the etching at the bottom of the hole H may be accelerated as compared to the conventional method.

As can be seen from the results represented in FIGS. 5 and 6, when the RF power LF is supplied to the lower electrode as the output of the low-frequency pulse during the etching, the roundness of the hole H may be improved, and the bowing, which has the trade-off relationship with the roundness, may also be suppressed.

The description of the plasma processing performed on the substrate W using the plasma processing apparatus 1 of an embodiment is continued below.

When the mask pattern is formed by the etching of the organic material layer M, the supply of the RF power HF and the supply of the RF power LF from the RF power supply 31 and the supply of the processing gas by the gas supply unit 20 are stopped.

Next, a processing gas including an etching gas for the etching target layer E is supplied from the gas supply unit 20 into the plasma processing space 10s through the center gas injector 13. The etching gas for the etching target layer E may be at least one gas selected from the group consisting of, for example, CF₄, CHF₃, and O₂. The processing gas may include a dilution gas such as Ar gas. Further, the first RF generation unit 31a supplies the RF power HF for plasma generation to the antenna 14, to excite the processing gas thereby generating plasma. Then, the substrate W is etched by the generated plasma. During the etching process, as illustrated in FIG. 2C, the etching target layer E and the underlying layer G are etched using the organic material layer M as a mask, and the mask pattern is transferred to the substrate W.

Because the mask pattern (hole H) has been formed appropriately, that is, with a shape in which the roundness is satisfactory and the bowing is suppressed, on the organic material layer M, the mask pattern may be appropriately transferred to the etching target layer E during the etching process of the etching target layer E.

Then, when the transfer of the mask pattern to the etching target layer E formed on the surface of the substrate W is completed, the etching process on the etching target layer E is terminated. When terminating the etching process, first, the supply of the RF power HF from the RF power supply 31 and the supply of the processing gas by the gas supply unit 20 are stopped. Further, in a case where the RF power LF has been supplied during the plasma processing, the supply of the RF power LF is also stopped. Then, the supply of the heat transfer gas to the back surface of the substrate W is stopped, and the adsorption of the substrate W by the electrostatic chuck is terminated.

Then, the etched substrate W is carried out from the plasma processing chamber 10 by a substrate transfer mechanism (not illustrated), and a series of processes for the plasma processing on the substrate W is terminated. In the present embodiment, the etching of the organic material layer M and the etching of the etching target layer E are performed in the common plasma processing apparatus 1. However, the etchings may be performed using separate plasma processing apparatuses, respectively.

As described above, according to the embodiment above, when etching the organic material layer M, the bias RF power LF is supplied to the lower electrode as the output of the low-frequency pulse, so that the roundness at the bottom of the hole H (mask pattern) may be appropriately improved, and the occurrence of bowing at the side wall of the hole H may be suppressed. Conventionally, in the case of attempting to improve the roundness of the hole H, the bowing in the trade-off relationship with the roundness has occurred in the hole H. In contrast, according to the embodiment above, the roundness of the hole H may be appropriately improved, and the bowing may be suppressed, by supplying the RF power LF to the lower electrode as the output of the low-frequency pulse.

At this time, the roundness and the bowing of the hole H may be more appropriately improved by controlling the pulse frequency of the RF power LF to 2 Hz or more and less than 100 Hz and the duty ratio to 20% or more to 90% or less, and preferably, controlling the pulse frequency to 2 Hz or more to 50 Hz or less and the duty ratio to 30% or more and 90% or less.

Specifically, it may be confirmed that the hole H formed by the etching method described above has the roundness of 0.90 or more and the bowing CD value (BB Bias) of 40 nm or less, as illustrated in FIGS. 5 and 6.

In the embodiment above, the roundness and the bowing of the hole H are improved by controlling the pulse frequency of the RF power LF and the duty ratio. However, the controllable elements in the etching process according to the present disclosure are not limited thereto.

As illustrated in FIG. 5, in the embodiment above, the roundness of the hole H is improved by reducing the ON/OFF cycle (pulse frequency) while controlling the duty ratio, which is the ratio of the ON time of the RF power LF, to be constant at 50%. Meanwhile, as can be seen from FIG. 5, the roundness of the hole H may also be improved by increasing the OFF time while controlling the duty ratio, which is the ratio of the ON time of the RF power LF, to be constant at 50%. That is, the roundness of the hole H may be improved by controlling the OFF time of the RF power LF supplied in the pulse form.

Specifically, as illustrated in FIG. 5, by supplying the RF power LF to the lower electrode as the pulse output and controlling the OFF time of the pulse output to 10 msec or longer, the roundness and the bowing of the hole H may be improved as in the embodiment above. In an embodiment, the pulse frequency of the RF power LF and the duty ratio may be set such that the OFF time of the pulse output is 10 msec or longer. For example, when the pulse frequency of 50 Hz is selected, the duty ratio may be set to % or less. When the pulse frequency of 2 Hz is selected, the duty ratio may be set to 98% or less. For example, when the duty ratio is 20%, the pulse frequency of the RF power LF may be set to 80 Hz or less. When the duty ratio is 90%, the pulse frequency of the RF power LF may be set to 10 Hz or less. In another embodiment, the duty ratio of the pulse output may be controlled to 20% or more and 60% or less, and preferably, %.

From the results of the Examples above, it may be understood that the roundness of the hole H may be improved by supplying the RF power LF to the lower electrode as the low-frequency pulse and increasing the reaction time (enhancing the reactivity) between the oxygen radicals generated in the plasma processing space 10s and the organic material layer M. In consideration of this point, it may be understood that the roundness of the hole H may be further improved by, for example, raising the pressure or temperature inside the plasma processing chamber 10 or increasing the ratio of the oxygen-containing gas in the processing gas so as to enhance the reactivity between the oxygen radicals and the organic material layer M, in addition to supplying the RF power LF as the low-frequency pulse output.

In the embodiment above, for example, the second RF generation unit 31b supplies the bias RF signal (RF power LF) to the lower electrode. However, the type of bias power is not limited thereto. Specifically, instead of or in addition to the bias RF signal from the second RF generation unit 31b, a bias DC voltage (bias DC signal) may be supplied to the lower electrode from the bias DC generation unit 32a of the DC power supply 32 illustrated in FIG. 1. The bias DC voltage may be supplied to the lower electrode such that a negative potential is generated on the substrate W. In an embodiment, the bias DC voltage is supplied to the lower electrode as a pulse voltage having the negative polarity. In this case, the pulse voltage may be a square wave pulse, a triangular wave pulse, an impulse, or pulses having other voltage waveforms.

Even when the DC voltage is supplied to the lower electrode from the bias DC generation unit 32a, the DC voltage may be pulsed having the OFF time of 10 msec, so that the deterioration of the roundness of the hole H may be suppressed, and the occurrence of bowing at the side wall of the hole H may be appropriately suppressed.

In the embodiment above, for example, the etching process is performed in the plasma processing apparatus 1 by the ON/OFF control of the RF power LF. However, as described above, the etching process may be performed in the plasma processing apparatus 1 by the High/Low control of the RF power LF, instead of the ON/OFF control.

Specifically, during the etching, as illustrated in FIG. 4, the first period and the second period are repeated at a predetermined cycle. In the first period, the RF power LF, which is the bias power, is supplied to the substrate support body at the first level (High level). In the second period, the RF power LF, which is the bias power, is supplied to the substrate support body at the second level (Low level) lower than the first level.

The second period of the present embodiment, during which the RF power LF is supplied at the second level (Low level), corresponds to the OFF time of the above-described embodiment. In the second period, ions attracted to the bottom of the hole H decrease, and a polymer is formed as a protective film on the side wall of the hole H.

Further, the first period of the present embodiment, during which the RF power LF is supplied at the first level (High level), corresponds to the ON time of the above-described embodiment. In the first period, while protecting the side wall of the hole H by the polymer (protective film) formed on the side wall of the hole H, ions are actively attracted into the hole H so that the etching at the bottom may be proceeded.

As a result of intensive study, the inventors of the present disclosure have confirmed that even when the RF power LF is supplied to the substrate support body by the High/Low control, the etching may also be proceeded under the same conditions as those in the ON/OFF control.

That is, in the cycle including the first and second periods, the time of the second period may be controlled to 10 msec or longer, so that the roundness and the bowing of the hole H may be improved as in the above-described embodiment.

At this time, by controlling the pulse frequency of the RF power LF to 2 Hz or more and less than 100 Hz and the duty ratio to 20% or more to 90% or less, preferably, the pulse frequency to 2 Hz or more to 50 Hz or less and the duty ratio to 30% or more and 90% or less, the roundness and the bowing of the hole H may be more appropriately improved as in the above-described embodiment.

Specifically, it may be confirmed that the hole H formed by the etching method according to the present embodiment also has the roundness of 0.90 or more and the bowing CD value (BB Bias) of 40 nm or less, as in the etching method of the above-described embodiment using the ON/OFF control.

Further, in the case where the RF power LF is supplied by the High/Low control, the “duty ratio” refers to the ratio of the first period (time during which the RF power LF is supplied at the first level) per cycle of the RF power (first period+second period).

Further, in the case where the RF power LF is supplied by the High/Low control, the “pulse frequency” refers to the frequency to switch the RF power between the High level and the Low level. In other words, in the case of the High/Low control, the “pulse frequency” indicates a pulse frequency defining a cycle of at least one of the first and second periods.

In the embodiments above, for example, an ACL film is formed on the substrate W as the organic material layer M. However, the type of the organic material layer M and the number of stacked layers are not limited thereto.

In the embodiments above, for example, the etching target layer E and the underlying layer G are stacked on the substrate W. However, the types of the etching target layer E and the underlying layer G and the number of stacked layers are not limited thereto.

According to the present disclosure, a hole with a high aspect ratio may be appropriately formed in an organic material layer that serves as a mask for forming patterns in an etching target layer.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) providing a substrate processing apparatus including
a processing chamber configured to form a processing space,
a substrate support provided inside the processing chamber and configured to hold a substrate, and
a power supply configured to supply a bias power to at least the substrate support;
(b) providing the substrate on the substrate support, the substrate including an underlying layer and an organic material layer on the underlying layer;
(c) generating plasma in the processing chamber; and
(d) repeating a predetermined cycle including an ON time during which the bias power is supplied to the substrate support and an OFF time during which the bias power is not supplied to the substrate support,
wherein, in (d), the OFF time is 10 msec or longer.

2. The method according to claim 1, wherein a frequency defining the cycle is 2 Hz or more and less than 100 Hz.

3. The method according to claim 2, wherein the frequency defining the cycle is 2 Hz or more and 50 Hz or less.

4. The method according to claim 1, wherein a duty ratio of the bias power is set to 20% or more and 90% or less.

5. The method according to claim 4, wherein the duty ratio is adjusted by changing the ON time while maintaining the OFF time constant.

6. The method according to claim 1, wherein the bias power is a radio-frequency power.

7. The method according to claim 1, wherein the bias power is a DC power.

8. The method according to claim 1, wherein at least one of a pressure in the processing space, a temperature in the processing space, and a ratio of an oxygen-containing gas in a processing gas of the processing space is further controlled.

9. The method according to claim 1, wherein the organic material layer includes an amorphous carbon film.

10. A method for etching a substrate, the method comprising:
(a) providing a substrate on a substrate support in a processing chamber, the substrate including an underlying layer and an organic material layer on the underlying layer; and
(b) forming a recess in the organic material layer using a plasma generated from a processing gas including an oxygen-containing gas,
wherein in (b), following two periods are repeated:
(b1) a first period, in which a bias power is supplied to the substrate support at a first level to etch the organic material layer, and
(b2) a second period, in which the bias power is not supplied to the substrate support or is supplied to the substrate support at a second level lower than the first level to form a protective film on a side wall of the recess.

11. The method according to claim 10, wherein during the first period, a bottom of the recess is etched while protecting the side wall of the recess by the protective film.

12. The method according to claim 10, wherein the second period is 10 msec or longer.

13. The method according to claim 10, wherein at least one of a frequency defining a cycle of the first period and a ratio of the first period to a total time of the first and second periods is controlled such that the second period becomes 10 msec or longer.

14. The method according to claim 13, wherein the frequency defining the cycle of the first period is 2 Hz or more and less than 100 Hz.

15. The method according to claim 13, wherein the ratio of the first period to the total time of the first and second periods is 20% or more and 90% or less.

16. The method according to claim 10, wherein the oxygen-containing gas includes at least one gas selected from the group consisting of CO gas, CO₂ gas, O₂ gas, O₃ gas, COS gas, and H₂O gas.

17. The method according to claim 10, wherein the processing gas further includes an inert gas.

18. The method according to claim 10, wherein the recess formed in the organic material layer in (b2) has a roundness of 0.90 or more and a bowing CD value of 40 nm or less.

19. An etching apparatus comprising:
a processing chamber;
a substrate support in the processing chamber;
a plasma generator; and
a controller configured to cause:
(a) placing a substrate on the substrate support in the processing chamber, the substrate including an underlying layer and an organic material layer on the underlying layer, and
(b) forming a recess in the organic material layer using a plasma generated from a processing gas including an oxygen-containing gas, and
wherein in (b), following two periods are repeated:
(b1) a first period, in which a bias power is supplied to the substrate support at a first level to etch the organic material layer, and
(b2) a second period, in which the bias power is not supplied to the substrate support or the bias power is supplied to the substrate support at a second level lower than the first level to form a protective film on a side wall of the recess.
